(19) United States
(12) Patent Application Publication
(10) Pub. No.: US 2022/0384624 A1
(43) Pub. Date: Dec. 1, 2022

(54) SEMICONDUCTOR DEVICE INCLUDING AN RC-IGBT

(71) Applicant: Infineon Technologies Austria AG, Villach (AT)

(72) Inventors: Matteo Dainese, Muenchen (DE); Sebastian Maass, München (DE); Hans-Joachim Schulze, Taufkirchen (DE)

(21) Appl. No.: 17/746,482

(22) Filed: May 17, 2022

(30) Foreign Application Priority Data
May 28, 2021 (DE) 102021113880.9

(51) Int. Cl. H01L 29/739; H01L 27/07; H01L 29/08; H01L 29/861; H01L 29/66; H01L 29/16

(52) U.S. Cl. CPC H01L 29/7397; H01L 27/0727; H01L 29/0834; H01L 29/8613; H01L 29/66136; H01L 29/1608; H01L 29/66333

(57) ABSTRACT

A semiconductor device is proposed. The semiconductor device includes a semiconductor substrate including a RC-IGBT with a diode area. The diode area includes a p-doped anode region and an n-doped emitter efficiency adjustment region. At least one of the p-doped anode region or the n-doped emitter efficiency adjustment region includes deep level dopants.

### TECHNICAL FIELD

The present disclosure is related to a semiconductor device, in particular to a semiconductor device including a reverse conducting insulated gate bipolar transistor, RC-IGBT.

### BACKGROUND

Technology development new generations of semiconductor devices, e.g. RC-IGBTs, aims at improving electric device characteristics and reducing costs by shrinking device geometries. Although costs may be reduced by shrinking device geometries, a variety of tradeoffs and challenges have to be met when increasing device functionalities per unit area. For example, a trade-off between switching efficiency and softness as a function of temperature requires design optimization.

There may be a desire for improving a design window for softness at low temperature and/or switching efficiency at high temperature.

### SUMMARY

An example of the present disclosure relates to a semiconductor device. The semiconductor device includes a semiconductor substrate comprising a RC-IGBT with a diode area. The diode area comprises a p-doped anode region and an n-doped emitter efficiency adjustment region. At least one of the p-doped anode region or the n-doped emitter efficiency adjustment region includes deep level dopants.

Another example of the present disclosure relates to a method of manufacturing a semiconductor device. The method includes forming a RC-IGBT with a diode area in a semiconductor substrate. Forming the diode area comprises forming a p-doped anode region, and forming an n-doped emitter efficiency adjustment region. At least one of the D-doped anode region or the n-doped emitter efficiency adjustment region includes deep level dopants.

### BRIEF DESCRIPTION OF THE DRAWINGS

The accompanying drawings are Included to provide a further understanding of the embodiments and are incorporated in and constitute a part of this specification. The drawings illustrate examples of semiconductor devices and together with the description serve to explain principles of the examples. Further examples are described in the following detailed description and the claims.

FIG. 1A is schematic plan view for illustrating an example of a RC-IGBT including an IGBT area and a diode area.

FIGS. 1B to 1I are schematic cross-sectional views for illustrating different designs of the diode area of the RC-IGBT of FIG. 1A.

FIGS. 2A to 2C are schematic top views for illustrating exemplary layouts of the diode area and the IGBT area surrounded by an edge termination area.

FIGS. 3A to 3C are schematic cross-sectional views of the diode area of RC-IGBTs that are based on she examples illustrated in FIGS. 1B to 1D, respectively.

FIG. 4 is a schematic cross-sectional view for illustrating an example of the diode area and the IGBT area of an exemplary RC-IGBT.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” describes a permanent low resistive connection between electrically connected elements, for example a direct contact between the concerned elements or a low-resistive connection via a metal and/or heavily doped semiconductor material. The term “electrically coupled” includes that one or more intervening element (s) adapted for signal and/or power transmission may be connected between the electrically coupled elements, for example, elements that are controllable to temporarily provide a low resistive connection in a first state and a high-resistive electric decoupling in a second state. An ohmic contact is a non-rectifying electrical junction.

Ranges given for physical dimensions include the boundary values. For example, a range for a parameter y from a to b reads as a ≤y≤b. The same holds for ranges with one boundary value like “at most” and “at least”.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

An example of a semiconductor device may include a semiconductor substrate comprising a RC-IGBT with a diode area. The diode area may include a p-doped anode region, and an n-doped emitter efficiency adjustment region. At least one of the anode region or the n-doped emitter efficiency adjustment region may include deep level dopants.

The semiconductor device may be an integrated circuit, or a discrete semiconductor device or a semiconductor module, for example. The semiconductor device may be or include a power semiconductor device, e.g. a vertical power semiconductor device having a load current flow between a first main surface and a second main surface that is located opposite to the first main surface. The semiconductor device may be or may include a power semiconductor. PC-IGIBT. The power semiconductor device may be configured to conduct currents of more than 1A or more than 10 A or even more than 30 A, and may be further configured to block voltages between load terminals, e.g. between emitter and collector of an RC-IGBT in the range of several hundreds of up to several thousands of volts, e.g. 400 V, 650V, 1.2 kV, 7 kV, 3.3 kV, 4.5 kV, 5.5 kV, 6 kV, 6.5 kV. The blocking voltage may correspond to a voltage class specified in a datasheet of the power semiconductor device, for example.

The semiconductor substrate may include or consist of a semiconductor material from the group IV elemental semiconductors, IV-IV compound semiconductor material, III-V compound semiconductor material, or II-VI compound semiconductor material. Examples of semiconductor materials from the group IV elemental semiconductors include, inter alia, silicon (Si) and germanium (Ge). Examples of IV-IV compound semiconductor materials include, inter alia, silicon carbide (SiC) and silicon germanium (SiGe). Examples of III-V compound semiconductor material include, inter alia, gallium arsenide (GaAs), gallium nitride (GaN), gallium phosphide (GaP), indium phosphide (InP), indium gallium nitride (InGaN) and indium gallium arsenide (InGaAs). Examples of II-VI compound semiconductor materials include, inter alia, cadmium telluride (CdTe), mercury-cadmium-telluride (CdHgTe), and cadmium magnesium telluride (CdMqTe). For example, the semiconductor substrate may be or may include a Czochraiski (CZ), e.g. a magnetic Czochraiski, MCZ, or a float zone (FZ), or an epitaxially deposited silicon semiconductor substrate.

The first main surface may be a front surface or a top surface of the semiconductor device, and the second surface may be a back surface or a rear surface of the semiconductor device, for example. The semiconductor substrate may be attached to a lead frame via the second main surface, for example. Over the first main surface of the semiconductor substrate, bond pads may be arranged and bond wires may be bonded on the bond pads.

Dopants usually create impurity levels within the energy bandgap of the semiconductor substrate. Impurity levels energetically close to the band edge (either conduction band minimum or valence band maximum) are called “shallow” level dopants, while those far away from the band edge are called “deep” level dopants. For a silicon semiconductor substrate, impurity levels energetically closer than. 100 meV to the band edge may be called shallow level dopants while those further away than 100 meV may be called deep level dopants. For a silicon carbide semiconductor substrate, impurity levels energetically closer than 250 meV to the band edge may be called shallow level dopants while those further away than 250 meV may be called deep level dopants. The fraction of dopants ionized to create electrons or holes depends on temperature and the position of the impurity level measured from the Fermi level. In a semiconductor substrate doped with shallow level dopants, at a moderate temperature such as room temperature, the donors (acceptors) are nearly all ionized. A semiconductor substrate doped with deep level dopants, on the other hand, requires high thermal energy and thereby a high temperature to ionize the dopants.

The emitter efficiency adjustment region may be configured to adjust the emitter efficiency of the diode area for optimizing the dynamic behavior of the semiconductor device. The higher the doping level of the emitter efficiency adjustment region is for a certain level of emitter doping, the lower is the emitter efficiency and therefore the turn-off losses of such a device are reduced due to a reduced flooding of the drift zone with free charge carriers.

Along a vertical direction perpendicular to the first main surface, the emitter efficiency adjustment region may turn into a drift region, e.g. an n-doped drift region. The drift region is arranged between the emitter efficiency adjustment region and the second main surface. An impurity or doping concentration in the drift region may gradually or in steps increase or decrease with increasing distance to the first main surface at least in portions of its vertical extension. According to other examples the impurity concentration in the drift region may be approximately uniform in vertical direction. For PC-IGBTs or diodes based on silicon, a mean impurity concentration in the drift region may be between 5×10¹² cm⁻³ and 1×10¹⁵ cm⁻³, for example in a range from 1×10¹³ cm⁻³ to 2×10¹⁴ cm⁻³. In the case of a semiconductor device based on SiC, a mean impurity concentration in the drift region may be between 5×10¹⁴ cm-3 and 1×10¹⁷ cm⁻³, for example in a range from 1×10¹⁵ cm⁻³ to 2×10¹⁶ cm⁻³. A vertical extension of the drift region may depend on voltage blocking requirements, e.g. a specified voltage class, of the vertical power semiconductor device. When operating the vertical power semiconductor device in voltage blocking mode, a space charge region may vertically extend partly or totally through the drift region depending on the blocking voltage applied to the vertical power semiconductor device. When operating the vertical power semiconductor device at or close to the specified maximum blocking voltage, the space charge region may reach or penetrate into a field stop region. The field stop region is configured to prevent the space charge region from further reaching to the cathode or collector at the second surface of the semiconductor substrate.

The p-doped anode region may be electrically connected to a first electrode at the first main surface. The first electrode may be a first load terminal L1, e.g. an emitter terminal of the RC-IGBT also utilized as an anode terminal of the diode area, and may include or consist of a conductive material or a combination of conductive materials, for example a doped semiconductor material (e.g., a degenerate doped semiconductor material) such as doped polycrystalline silicon, metal or metal compound, for example. The first load terminal L1 may also include a combination of these materials, e.g. a liner or adhesion material and an electrode material. Exemplary contact or electrode materials include one or more of titanium nitride (TiN) and tungsten (W), aluminum (Al), copper (Cu), alloys of aluminum or copper, for example AlSi, AlCu or AlSiCu, nickel (Ni), titanium (Ti), tungsten (W), tantalum (Ta), silver (Aq), gold (Au), platinum (Pt), palladium (Pd), for example.

A deep level donor in the emitter efficiency adjustment region may allow for counteracting an increase of the reverse recovery charge, Qrr, and, accordingly, turn-off switching losses with increasing temperature by tuning the anode efficiency. The effectiveness of the emitter efficiency adjustment region increases with temperature due to the deep level donors that may not be fully ionized at room temperature and whose degree of ionization increases when reaching the high temperature range of operation, e.g. 125° C. to 200° C. so that the emitter efficiency of the anode-side emitter region decreases with increasing temperature.

A deep level acceptor in the anode region may allow for reducing the anode emitter efficiency and the peak reverse recovery current in the low temperature range of the safe operating area, e.g. at temperatures between −40° C. to 0° C. due to a decrease of is of the deep acceptor at low temperatures and with it a reduced effective doting level of the anode-side emitter.

For example, at least one of the p-doped anode region or the n-doped emitter efficiency adjustment region may include a combination of shallow level dopants and deep level dopants. Adding shallow level dopants to the deep level dopants in the anode region and/or the n-doped emitter efficiency adjustment region may counteract a limited solubility of deep level dopants in a silicon semiconductor substrate, for example, so that the targeted total dopant dose in the emitter efficiency adjustment layer or the emitter layer may be achieved.

For example, the semiconductor substrate may be a silicon semiconductor substrate. The anode region may include at least one of boron, aluminum or gallium, as a shallow level acceptor and indium as a deep level acceptor.

For example, the semiconductor substrate may be a silicon semiconductor substrate. The n-doped emitter efficiency adjustment region may include at least one of phosphorus, arsenic or antimony as a shallow level donor and at least one of selenium, tellurium or sulphur as a deep level donor.

For example, the semiconductor substrate may be a silicon carbide semiconductor substrate. The anode region may include aluminum as a shallow level acceptor and at least one of gallium or boron as a deep level acceptor.

For example, the semiconductor substrate may be a silicon carbide semiconductor substrate. The n-doped emitter efficiency adjustment region may include at least one of phosphorous or nitrogen as a shallow level donor and at least one of chromium, selenium or sulphur as a deep level donor.

For example, a ratio between shallow and deep level donor concentrations may range from 0 to a factor of twenty, or to a factor of ten, or to a factor of five, or to a factor of two in at least a section along an extension of the n-doped emitter efficiency adjustment region perpendicular to a first main surface, e.g. along a vertical direction, of the semiconductor substrate.

For example, a ratio between shallow and deep level acceptor concentrations may range from 0 to a factor of twenty, or to a factor of ten, or to a factor of five, or to a factor of two in at least a section along an extension of the anode region perpendicular to the first main surface, e.g. along a vertical direction.

For example, the semiconductor device may further comprise a plurality of first trench structures extending perpendicular to a first main surface, e.g. along a vertical direction. The p-doped anode region may be laterally confined by a pair of the plurality of first trench structures. The p-doped anode region may directly adjoin to opposite sidewalls of the pair of the plurality of first trench structures, for example.

For example, the n-doped emitter efficiency adjustment region may be at least partly laterally confined by the pair of the plurality of flrst trench structures.

For example, each trench structure of the pair of the plurality of first trench structures may include a dielectric and an electrode. For example, the electrode may be electrically connected to a first load terminal of the IGBT, e.g. an emitter terminal. The trench structure may be configured as a field plate trench structure that may contribute to charge compensation in a blocking operation of the RC-IGBT, for example.

For example, the RC-IGBT may include a plurality of second trench structures in an IGBT area. The plurality of second trench structures may extend perpendicular to the first main surface of the semiconductor substrate. Each of the second trench structures may include a gate dielectric, and at least some of the second trench structures may include a gate electrode electrically connected to a gate terminal.

For example, the diode area may be at least partly surrounded by the IGBT area. For example, a larger part, e.g. a predominant part of the diode area may be surrounded by an edge termination area and a smaller part of the diode area may be surrounded by the IGBT area. According to another example, a larger part, e.g. a predominant part of the diode area may be surrounded by the IGBT area and a smaller pars of the diode area may be surrounded by the edge termination area. According so yet another example, the diode area may be fully surrounded by the IGBT area.

For example, a first width of a mesa region between the pair of the plurality of first trench structures may be larger than a second width of a mesa region between a pair of the plurality of second trench structures. This may allow for separately optimizing electric characteristics in the IGBT area and in the diode area.

For example, the p-doped anode region laterally confined by the pair of the plurality of first trench structures may include a combination of shallow level dopants and deep level dopants. The n-doped emitter efficiency adjustment region laterally confined by a second pair of the plurality of first trench structures may include a combination of shallow level dopants and deep level dopants. For example, diode mesa regions confined by different pairs of the first trench structures may also differ with respect to at least one of a number of different species of deep level dopants, species, e.g. element, of deep level dopant(s), concentration of deep level dopant(s), number of different species of shallow level dopants, species, e.g. element, of shallow level dopant(s), concentration of shallow level dopant(s) in the n-doped emitter efficiency adjustment region and/or the p-doped anode region. Likewise, also segments along a single diode mesa region may differ with respect to at least one of number of different species of deep level dopants, species, e.g. element, of deep level dopant(s), concentration of deep level dopant(s), number of different species of shallow level dopants, species, e.g. element, of shallow level dopant(s), concentration of shallow level dopant in the n-doped emitter efficiency adjustment region and/or the p-doped anode region. This may allow for a further degree of freedom when adjusting the electric characteristic in the diode area, for example.

For example, at least one of i) the n-doped emitter efficiency adjustment region laterally confined by the pair of the plurality of first trench structures, or ii) the p-doped anode region laterally confined by the second pair of the plurality of first trench structures may include only one of shallow level dopants and deep level dopants. For example, diode mesa regions confined by different pairs of the first trench structures may also differ with respect to at least one of a number of different species of deep level dopants, species, e.g. element, of deep level dopant(s), concentration of deep level dopant(s), number of different species of shallow level dopants, species, e.g. element, of shallow level dopant(s), concentration of shallow level dopant (s) in the n-doped emitter efficiency adjustment region and/or the p-doped anode region. Likewise, also segments along a single diode mesa region may differ with respect to at least one of number of different species of deep level dopants, species, e.g. element, of deep level dopant(s), concentration of deep level dopant (s), number of different species of shallow level dopants, species, e.g. element, of shallow level dopant(s), concentration of shallow level dopant(s) in the n-doped emitter efficiency adjustment region and/or the p-doped anode region. This may allow for a further degree of freedom when adjusting the electric characteristic in the diode area, for example.

For example, the n-doped emitter efficiency adjustment region may include a plurality of emitter efficiency adjustment sub-regions spaced from one another along a longitudinal direction of the plurality of first trench structures. For example, the plurality of emitter efficiency adjustment sub-regions spaced from one another along the longitudinal direction of the plurality of first trench structures may also differ with respect to at least one of number of different species of deep level dopants, species, e.g. element, of deep level dopant(s), concentration of deep level dopant (s), number of different species of shallow level dopants, species, e.g. element, of shallow level dopant(s), concentration of shallow level dopant (s).

For example, the semiconductor device may further comprise a drift region arranged between the emitter efficiency adjustment region and the second main surface of the semiconductor substrate. A minority carrier lifetime in the drift region may be larger than 20 μs, or even larger than 40μs, or even larger than 100 μs. The drift region may be free of a substantial concentration of lifetime-killing impurities creating deep recombination centers in the energy bandgap, e.g. metals such as platinum, chromium or gold which is enabled by the reduced emitter efficiency by implementing the emitter efficiency adjustment region or by using deep level acceptors for doping the anode-side emitter.

For example, a wiring area over the first main surface may include a silicate glass, wherein the silicate glass includes only phosphosilicate glass out of a group of phosphosilicate glass and borophosphosilicate glass and undoped silicate glass. This may allow for reducing thermal budget for diffusion. In some other examples, e.g. processes involving rapid thermal annealing processes for forming the wiring area, also borophosphosilicate glass may be part of the wiring area, for example.

Functional or structural details described above with respect to features of the semiconductor device shall likewise apply to corresponding features of the method described below.

An example of a method of manufacturing a semiconductor device may include forming a RC-IGBT with a diode area in a semiconductor substrate. Forming the diode area may include forming a p-doped anode region, and forming an n-doped emitter efficiency adjustment region. At least one of the anode region or the emitter efficiency adjustment region may include deep level dopants.

For example, the method may further include forming a mask over a first main surface of the semiconductor substrate. At least one mesa region of the diode may be covered by the mask. A mask opening may be arranged over at least one other mesa region of the diode. Thereby, mesa regions may differ with respect to at least one of number of different species of deep level dopants, species, e.g. element, of deep level dopant(s), concentration of deep level dopant(s), number of different species of shallow level dopants, species, e.g. element, of shallow level dopant (s), concentration of shallow level dopant(s) in the n-doped emitter efficiency adjustment region and/or the p-doped anode region.

For example, the method may further include forming a wiring area including a silicate glass over the first main surface. The silicate glass may include only phosphosilicate glass out of a group of phosphosilicate glass, borophosphosilicate glass, and undoped silicate glass. This may allow for reducing thermal budget for diffusion. In some other examples, e.g. rapid thermal annealing processes used for forming the wiring area, also borophosphosilicate glass may be Part of the wiring area, for example.

For example, the method may further include forming a plurality of first trench structures extending perpendicular to the first main surface of the semiconductor substrate.

For example, forming the RC-IGBT may include forming a plurality of second trench structures in an IGBT area. The plurality of second trench structures may extend perpendicular to the first main surface of the semiconductor substrate. Each of the second trench structures may include a gate dielectric. At least some of the second trench structures may include a gate electrode electrically connected to a gate terminal over the first main surface. Trenches of the first trench structures and the second trench structures may be concurrently formed, e.g. by one or more common etch processes.

The examples and features described above and below may be combined.

Functional and structural details described with respect to the examples above shall likewise apply to the exemplary examples illustrated in the figures and described further below.

In the following, further examples of semiconductor devices are explained in connection with the accompanying drawings. Functional and structural details described with respect to the examples above shall likewise apply to the exemplary embodiments illustrated in the figures and described further below.

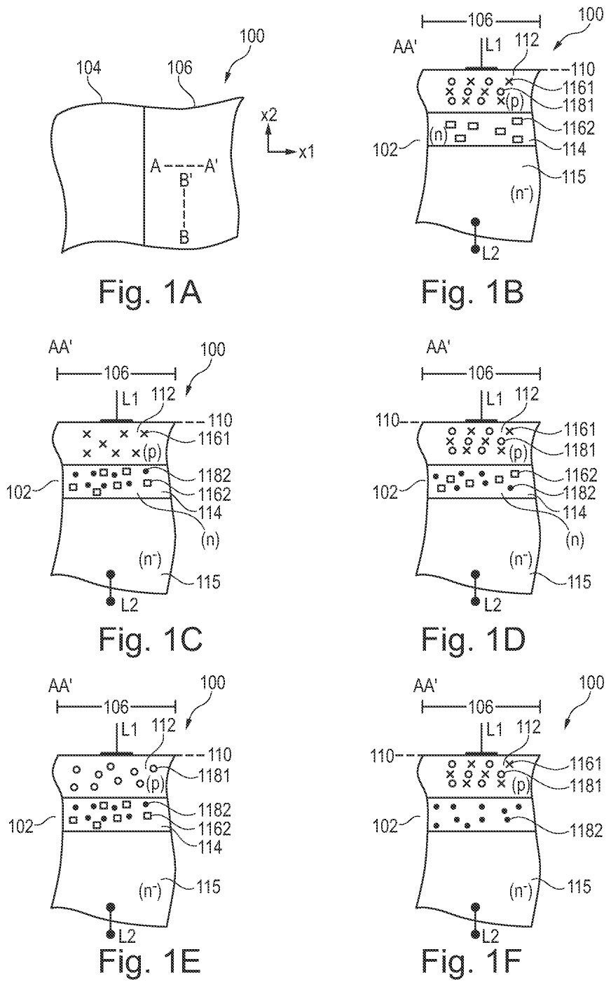

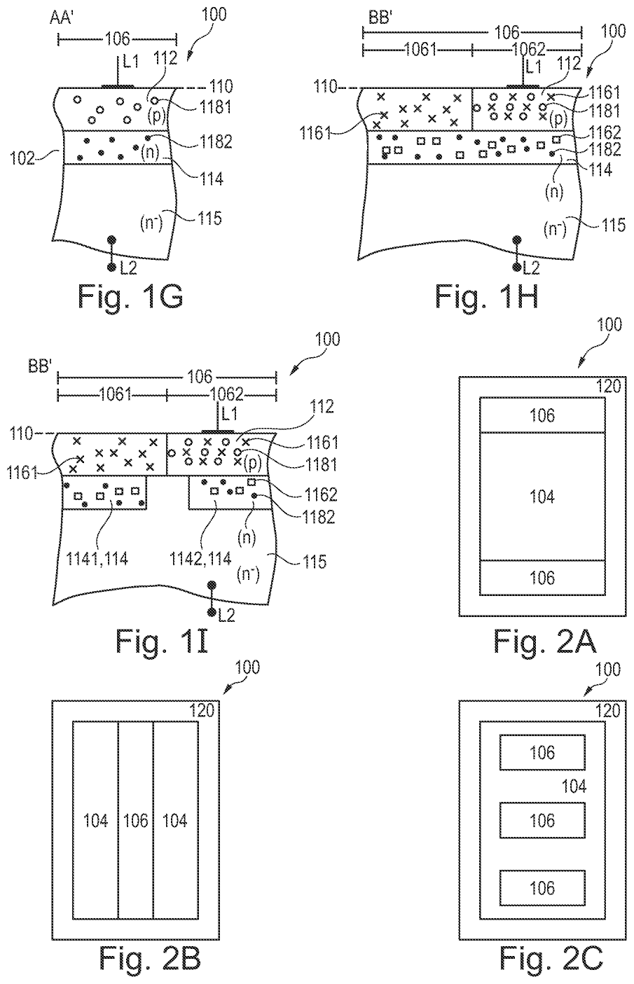

FIG. 1A schematically and exemplarily shows a plan view for illustrating a semiconductor device 100 including an RC-IGBT with a diode area 106 and an IGBT area 104.

The schematic cross-sectional views of FIGS. 1B to 1G illustrate exemplary cross-sectional views along a first lateral direction x1 of line AA′ in FIG. 1A. The diode area 106 includes a semiconductor substrate 102 comprising a p-doped anode region 112, an n-doped emitter efficiency adjustment region 114, and an n-doped drift region 115. The anode region 112 is electrically connected to a first load terminal L1, e.g. an emitter electrode or anode electrode of the RU-LIFT via a first main surface 110, e.g. front surface or top surface, of the semiconductor substrate 102.

At least one of the p-doped anode region 112 or the n-doped emitter efficiency adjustment region 114 includes deep level dopants.

Referring to the example illustrated in the cross-sectional view of FIG. 1B, the anode region 112 includes deep level dopants 1181 and shallow level dopants 1161, and the emitter efficiency adjustment region 114 includes shallow level dopants 1162 but no deep level dopants.

Referring to the example illustrated in the cross-sectional view of FIG. 1C, the anode region 112 includes shallow level dopants 1161 but no deep level dopants, and the emitter efficiency adjustment region 114 includes shallow level dopants 1162 and deep level dopants 1182.

Referring to the example illustrated in the cross-sectional view of FIG. 1D, the anode region 112 includes shallow level dopants 1161 and deep level dopants 1181, and the emitter efficiency adjustment region 114 includes shallow level dopants 1162 and deep level dopants 1182.

Referring to the example illustrated in the cross-sectional view of FIG. 1E, the anode region 112 includes deep level dopants 1181 but no shallow level dopants, and the emitter efficiency adjustment region 114 includes shallow level dopants 1162 and deep level dopants 1182.

Referring to the example illustrated in the cross-sectional view of FIG. IF, the anode region 112 includes deep level dopants 1181 and shallow level dopants 1161, and the emitter efficiency adjustment region 114 includes deep level dopants 1182 but no shallow level dopants.

Referring to the example illustrated in the cross-sectional view of FIG. 1G, the anode region 112 includes deep level dopants 1181 but no shallow level dopants, and the emitter efficiency adjustment region 114 includes deep level dopants 1182 but no shallow level dopants.

Each of the shallow level dopants 1161, 1162 and the deep level dopants 1181, 1182 may include one or more species, e.g. elements, of dopants. For example, phosphorus is one species or element for a shallow level dopant in the emitter efficiency adjustment region 114 in case of a semiconductor substrate 102 made of silicon. For example, phosphorus and antimony and arsenic are three species or elements for a shallow level dopant in the emitter efficiency adjustment region 114 in case of a semiconductor substrate 102 made of silicon.

The examples illustrated in FIGS. 1B to 1G may be combined in the diode area 106. For example, the examples illustrated in FIGS. 1B to 1G may be arranged in different sub-areas of the diode area 106. Also the concentrations of dopants may vary over the different sub-areas. The sub-areas may also have different lateral extents, for example. Moreover, the n-doped emitter efficiency adjustment region 114 may include a plurality of emitter efficiency adjustment sub-regions spaced from one another along a lateral direction.

Some of the above-identified variations are exemplarily illustrated in the schematic cross-sectional views of FIGS. 1H and 1I taken along a second lateral direction x2, e.g. a longitudinal direction of stripe-shaped diode cells, of line BB′ of FIG. 1A.

In the schematic cross-sectional view of FIG. 1H, in a first sub-area 1061 of the diode area 106, the dopants in the r-doped anode region 112 and the n-doped emitter efficiency adjustment region 114 are configured as illustrated in the example of 1C, and in a second sub-area 1062 of the diode area 106, the dopants in the p-doped anode region 112 and the n-doped emitter efficiency adjustment region 114 are configured as illustrated in the example of 1D.

The example in the schematic cross-sectional view of FIG. 1I differs from the example in the schematic cross-sectional view of FIG. 1H in that the n-doped emitter efficiency adjustment region 114 includes a plurality of emitter efficiency adjustment sub-regions 1141, 1142 spaced from one another the second lateral direction x2. The spacing may be varied along the second lateral direction x2, for example.

The examples illustrated in the figures may be combined and may further be combined with other designs of the dopants in the p-doped anode region 112 and the n-doped emitter efficiency adjustment region 114 not illustrated in the figures but disclosed as an example herein. By varying different designs of the p-doped anode region 112 and the n-doped emitter efficiency adjustment region 114, e.g. geometry, dose of doping, number and species/elements of dopants of shallow and/or deep level dopants, or lateral and vertical extent, a wide area in the design window for softness at low temperature and/or switching efficiency at high temperature in the diode performance can be accessed for tuning a RC-IGBT to the applications' need.

The diode area 106 may be at least partly surrounded by the IGBT area 104. Referring to the example illustrated in the plan view of FIG. 2A, a predominant part of the diode area 106 is surrounded by an edge termination area 120 and a smaller part of the diode area 106 is surrounded by or adjoins the IGBT area 104. Referring to the example illustrated in the plan view of FIG. 2B, a predominant part of the diode area 106 is surrounded by the IGBT area 104 and a smaller part of the diode area 106 is be surrounded by the edge termination area 120. Referring to the example illustrated in the plan view of FIG. 2C, the diode area 106 is fully surrounded by the IGBT area 104.

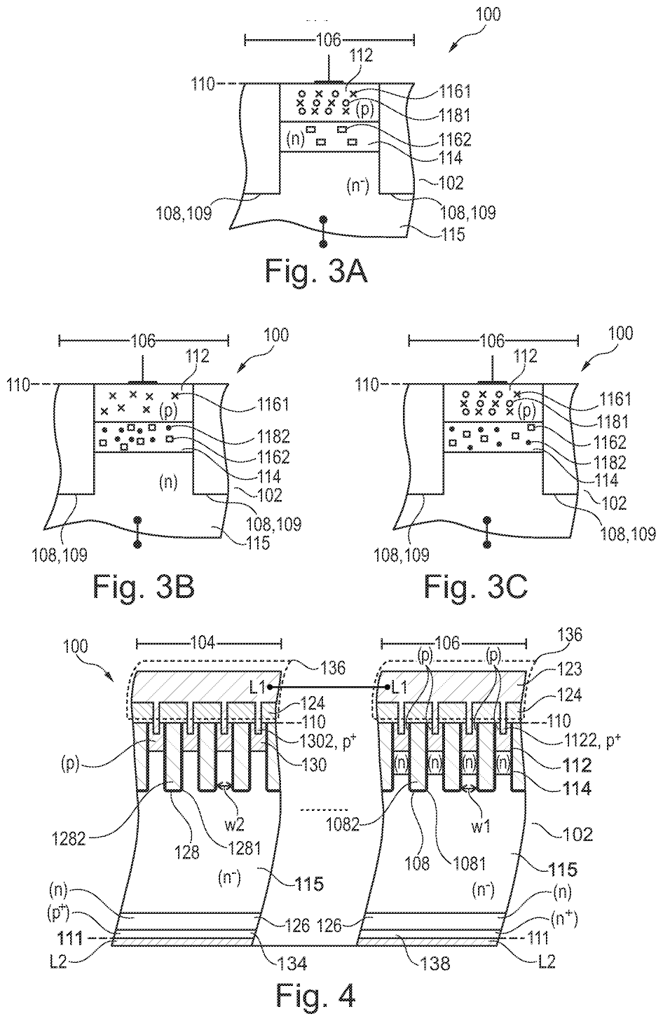

The schematic cross-sectional views of FIGS. 3A to 3C illustrate examples of the diode area 106 of RC-IGBTs that are based on the examples illustrated in FIGS. 1B to ID, respectively, but further include a plurality of first trench structures 108 extending perpendicular to the flrst main surface 110 of the semiconductor substrate 102. The p-doped anode region 112 is laterally confined by a pair 109 of the plurality of first trench structures 108. The n-doped emitter efficiency adjustment region 114 is at least partly laterally confined by the pair 109 of the plurality of first trench structures 108.

The schematic cross-sectional view of FIG. 4 illustrates an example of an RC-IGBT including a diode area 104 that may be configured as described in the examples above. The first load terminal L1 includes an electrode structure 123 that is electrically connected to the anode region 112 via an optional p⁺-doped anode contact: region 1122. An intermediate dielectric 124 is arranged between the electrode structure 123 and the first main surface 110. An n-doped field stop region 126 is arranged between the drift region 115 and the second load terminal L2 at a second main surface 111. At the second main surface ill, a p⁺-doped rear side emitter or collector region 134 is electrically connected to the second load terminal L2, e.g. a collector electrode, in the IGBT area 104, and an n⁺-doped contact region 138 is arranged at the second main surface 111 in the diode area 106. The n-doped contact region 138 may also be omitted in the diode area 106 in case that a doping concentration of the field stop region 126 is large enough for enabling an ohmic contact at the second main surface 111. Each of first trench structures 108 includes a dielectric 1081 and an electrode 1082. The electrode 1082 is electrically connected to the first load terminal L1, e.g. in a connection area not illustrated in FIG. 4.

The RC-IGBT further includes a plurality of second trench structures 128 in the IGBT area 104. The plurality of second trench structures 128 extends perpendicular to the first main surface 110 of the semiconductor substrate 102. Each of the second trench structures 128 includes a gate dielectric 1281, and at least some of the second trench structures 128 include a gate electrode 1282 electrically connected to a gate terminal. In some other second trench structures 128, the electrode may be electrically connected to a terminal different from the gate terminal, e.g. the first load terminal L1 and/or another reference voltage. The IGBT area 104 further includes a p-doped body region 130. The p-type body region 130 may be concurrently formed with at least part of the p-type anode region 112, e.g. by common shallow level acceptor ion implantation process(es). The p-type body region 130 is electrically connected to the electrode structure 123 of the first load terminal L1 via an optional et-doped body contact region 1302. For example, the et-doped body contact region 1302 and the p⁺-doped anode contact region 1122 may be concurrently formed, for example. An optional n-doped carrier confinement region may be arranged between the p-doped body region 130 and the n-doped drift region 115, e.g. in a mesa region between neighboring second trench structures 128 (not illustrated in FIG. 4).

A first width w1 of a mesa region between a pair of the plurality of first trench structures 108 may be equal to or even larger than a second width w2 of a mesa region between a pair of the plurality of second trench structures 128.

The drift region. 115 arranged between the emitter efficiency adjustment region 114 and the second main surface 111 of the semiconductor substrate 102 may have a minority carrier lifetime that is larger than 100 μs.

A wiring area 136 over the first main surface 110 that includes the electrode structure 123 and the intermediate dielectric may also include a silicate glass over the electrode structure 123. The silicate glass may include only phosphosilicate glass out of a group of phosphosilicate glass and borophosphosilicate glass, and undoped silicate glass, for example.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor substrate comprising a RC-IGBT with a diode area,
wherein the diode area comprises a p-doped anode region and an n-doped emitter efficiency adjustment region,
wherein at least one of the p-doped anode region or the n-doped emitter efficiency adjustment region includes deep level dopants,
wherein at least one of the p-doped anode region or the n-doped emitter efficiency adjustment region includes a combination of shallow level dopants and deep level dopants.

2. The semiconductor device of claim 1, wherein the semiconductor substrate is a silicon semiconductor substrate, and wherein the p-doped anode region includes at least one of boron, aluminum or gallium, as a shallow level acceptor and indium as a deep level acceptor.

3. The semiconductor device of claim 1, wherein the semiconductor substrate is a silicon semiconductor substrate, and wherein the n-doped emitter efficiency adjustment region includes at least one of phosphorus, arsenic or antimony as a shallow level donor and at least one of selenium, tellurium or sulphur as a deep level donor.

4. The semiconductor device of claim 1, wherein the semiconductor substrate is a silicon carbide semiconductor substrate, and wherein the p-doped anode region includes aluminum as a shallow level acceptor and at least one of gallium or boron as a deep level acceptor.

5. The semiconductor device of claim 1, wherein the semiconductor substrate is a silicon carbide semiconductor substrate, and wherein the n-doped emitter efficiency adjustment region includes at least one of phosphorous or nitrogen as a shallow level donor and at least one of chromium, selenium or sulphur as a deep level donor.

6. The semiconductor device of claim 1, wherein a ratio between shallow and deep level donor concentrations ranges from 0 to a factor of twenty in at least a section along an extension of the n-doped emitter efficiency adjustment region perpendicular to a first main surface of the semiconductor substrate.

7. The semiconductor device of claim 6, wherein a ratio between shallow and deep level acceptor concentrations ranges from 0 to a factor of twenty in at least a section along an extension of the p-doped anode region perpendicular to the first main surface.

8. The semiconductor device of claim 1, further comprising:
a plurality of first trench structures extending perpendicular to a first main surface of the semiconductor substrate, wherein the p-doped anode region is laterally confined by a pair of the plurality of first trench structures.

9. The semiconductor device of claim 8, wherein the n-doped emitter efficiency adjustment region is at least partly laterally confined by the pair of the plurality of first trench structures.

10. The semiconductor device of claim 8, wherein each trench structure of the pair of the plurality of first trench structures includes a dielectric and an electrode, and wherein the electrode is electrically connected to a first load terminal of the RC-IGBT.

11. The semiconductor device of claim 8, wherein the RC-IGBT comprises:
a plurality of second trench structures in an IGBT area, the plurality of second trench structures extending perpendicular to the first main surface of the semiconductor substrate, wherein each of the second trench structures includes a gate dielectric, and at least some of the second trench structures include a gate electrode electrically connected to a gate terminal.

12. The semiconductor device of claim 11, wherein the diode area is at least partly surrounded by the IGBT area.

13. The semiconductor device of claim 11, wherein a first width of a mesa region between the pair of the plurality of first trench structures is larger than a second width of a mesa region between a pair or the plurality of second trench structures.

14. The semiconductor device of claim 8, wherein the p-doped anode region laterally confined by the pair of the plurality of first trench structures includes a combination of shallow level dopants and deep level dopants, and the n-doped emitter efficiency adjustment region laterally confined by a second pair of the plurality of first trench structures includes a combination of shallow level dopants and deep level dopants.

15. The semiconductor device of claim 14, wherein at least one of the n-doped emitter efficiency adjustment region laterally confined by the pair of the plurality of first trench structures or the p-doped anode region laterally confined by the second pair of the plurality of first trench structures includes only one of shallow level dopants and deep level dopants.

16. The semiconductor device of claim 8, wherein the n-doped emitter efficiency adjustment region includes a plurality of emitter efficiency adjustment sub-regions spaced from one another along a longitudinal direction of the plurality of first trench structures.

17. The semiconductor device of claim 1, further comprising a drift region arranged between the emitter efficiency adjustment region and a second main surface of the semiconductor substrate, wherein a minority carrier lifetime in the drift region is larger than 100 μs.

18. The semiconductor device of claim 1, further comprising a wiring area over the first main surface, wherein the wiring area includes a silicate glass, and wherein the silicate glass includes only phosphosilicate glass out of a group of phosphosilicate glass and borophosphosilicate glass, and undoped silicate glass.

19. A method of manufacturing a semiconductor device, the method comprising:
forming a RC-IGBT with a diode area in a semiconductor substrate,
wherein forming the diode area comprises:
forming a p-doped anode region; and
forming an n-doped emitter efficiency adjustment region,
wherein at least one of the p-doped anode region or the n-doped emitter efficiency adjustment region includes deep level dopants,
wherein at least one of the p-doped anode region or the n-doped emitter efficiency adjustment region includes a combination of shallow level dopants and deep level dopants.

20. The method of claim 19, further comprising:
forming a mask over a first main surface of the semiconductor substrate,
wherein at least one mesa region of the diode area is covered by the mask, and
wherein a mask opening is arranged over at least one other mesa region of the diode area.

21. The method of claim 19, further comprising:
forming a wiring area that includes a silicate glass over a first main surface of the semiconductor substrate,
wherein the silicate glass includes only phosphosilicate glass out of a group of phosphosilicate glass and borophosphosilicate glass, and an undoped silicate glass.

22. The method of claim 19, further comprising:
forming a plurality of first trench structures extending perpendicular to a first main surface of the semiconductor substrate.

23. The method of claim 22, wherein forming the RC-IGBT comprises:
forming a plurality of second trench structures in an IGBT area, the plurality of second trench structures extending perpendicular to a first main surface of the semiconductor substrate,
wherein each of the second trench structures includes a gate dielectric, and at least some of the second trench structures include a gate electrode electrically connected to a gate terminal over the first main surface, and
wherein trenches of the first trench structures and the second trench structures are concurrently formed.
